(19) United States
(12) Patent Application Publication
(10) Pub. No.: US 2025/0203980 A1
(43) Pub. Date: Jun. 19, 2025

(54) VERTICAL FIELD-EFFECT TRANSISTOR STRUCTURE AND METHOD FOR PRODUCING A VERTICAL FIELD-EFFECT TRANSISTOR STRUCTURE

(71) Applicant: Robert Bosch GmbH, Stuttgart (DE)

(72) Inventor: Jens Baringhaus, Sindelfingen (DE)

(21) Appl. No.: 18/978,317

(22) Filed: Dec. 12, 2024

(30) Foreign Application Priority Data
Dec. 15, 2023 (DE) 10 2023 212 762.8

(51) Int. Cl. H10D 62/17; H10D 30/01; H10D 30/66; H10D 62/832

(52) U.S. Cl. CPC H10D 62/314; H10D 30/0297; H10D 30/668; H10D 62/8325

(57) ABSTRACT

A vertical field-effect transistor structure. The structure includes a substrate having a first substrate surface, a semiconductor layer located on the first substrate surface, from which semiconductor layer a plurality of fin structures anchored to the semiconductor layer are patterned out on a side of the semiconductor layer directed away from the first substrate surface, wherein a source region is formed at each end of the fin structures directed away from the substrate, and including a plurality of gate electrodes, wherein one of the gate electrodes is located between two adjacent fin structures and the fin structures and the semiconductor layer are electrically insulated from the gate electrodes using at least one gate dielectric, wherein a doped channel region is in each case located on a side of the source regions of the fin structures aligned with the substrate.

### FIELD

The present invention relates to a vertical field-effect transistor structure and to a method for producing a vertical field-effect transistor structure.

### BACKGROUND INFORMATION

FIG. 1A to 1D are a schematic cross-sectional view of a conventional FinMOS, which is known to the applicant as internal related art, along with associated profiles of the charge depth, fin width and threshold voltage Uth.

The conventional FinMOS shown schematically in FIG. 1A comprises a substrate wafer 10 having a first wafer surface 10a and a second wafer surface 10b directed away from the first wafer surface 10a. The FinMOS has an n-doped silicon carbide layer 12 epitaxially grown on the first wafer surface 10a. Fin structures 14 are patterned out of the silicon carbide layer 12 on a side of the silicon carbide layer 12 directed away from the substrate wafer 10, wherein the fin structures 14 anchored to the silicon carbide layer 12 are (substantially) strip-shaped. A longitudinal direction aligned parallel to the first wafer surface 10a can in each case be defined for the (almost) strip-shaped fin structures 14, in which longitudinal direction the fin structures 14 have their maximum extent. The longitudinal direction of the fin structures 14 is typically perpendicular to the [112̅0] direction of the silicon carbide layer 12. Each of the fin structures 14 has an n-doped source region 16 at its end directed away from the substrate wafer 10. Furthermore, each of the fin structures has a p-doped channel region 18 that is adjacent to the corresponding source region 16. A gate electrode 20 is in each case located between two adjacent fin structures 14, wherein a gate dielectric 22 electrically insulates the fin structures 14 and the silicon carbide layer 12 from the gate electrode 20. The conventional FinMOS shown in FIG. 1A further has a source electrode 24 arranged on a side of the fin structures 14 facing away from the substrate wafer 10 and a drain electrode 26 arranged on the second wafer surface 10b.

FIG. 1B shows the doping in the channel region 18. The doping or charge density LD in the channel region 18 is typically uniform in the vertical direction, i.e. constant in the depth direction. In combination with a homogeneous FB width of the fin in the channel region 18, this results in a homogeneous local threshold voltage Uth across the entire channel region 18 (e.g. in the regions 18.1, 18.2 and 18.3), as shown in FIG. 1D. The threshold voltage Uth is the voltage value at which the electric current just begins to flow through the channel of the FET.

However, the width FB of the fins is typically not homogeneous or constant, but usually increases from top to bottom in the vertical direction in conventional FinFETS as shown in FIG. 2A. This is illustrated in the profile of a fin width FB of a fin shown in FIG. 2C. The homogeneous dopant profile in the channel region 40 (see FIG. 2B) of the widening fin of the conventional FinFET then results in an inhomogeneous local threshold voltage Uth in the vertical direction through the channel region 40, as can be seen in FIG. 2D. As the fin width FB of the fin increases, the threshold voltage Uth also increases locally in the vertical direction or depth D, as shown in FIG. 2D. The increasing fin width FB of the fin thus leads to an inhomogeneous, gradually decreasing local threshold voltage Uth across the channel region 40 of the widening fin.

### SUMMARY

The present invention provides a vertical field-effect transistor structure and a method for producing a vertical field-effect transistor structure.

According to a first aspect, the present invention provides a vertical field-effect transistor structure. According to an example embodiment of the present invention, the vertical field-effect transistor structure comprising a substrate having a first substrate surface, a semiconductor layer located on the first substrate surface, from which semiconductor layer a plurality of fin structures anchored to the silicon carbide layer are patterned out on a side of the semiconductor layer directed away from the first substrate surface, wherein a source region is formed at each end of the fin structures directed away from the substrate, and comprising a plurality of gate electrodes, wherein one of the gate electrodes is located between two adjacent fin structures and the fin structures and the semiconductor layer are electrically insulated from the gate electrodes by means of at least one gate dielectric, wherein a doped channel region is in each case located on a side of the source regions of the fin structures aligned with the substrate, the doping of which doped channel region is adjusted to provide a predefined local threshold voltage profile along the depth of the particular fin structure.

According to a further aspect, the present invention provides a method for producing a vertical field-effect transistor structure. According to an example embodiment of the present invention, the method comprises the steps of: providing a semiconductor layer on a first substrate surface of a substrate; patterning a plurality of fin structures anchored to the semiconductor layer out of the semiconductor layer on a side of the semiconductor layer directed away from the first substrate surface, wherein a source region is formed at each end of the fin structures directed away from the substrate; forming a plurality of gate electrodes, wherein one of the gate electrodes is arranged between two adjacent fin structures and the fin structures and the semiconductor layer are electrically insulated from the gate electrodes by means of at least one gate dielectric; and adjusting a doping of channel regions, each of which is located on a side of the source regions of the fin structures aligned with the substrate, to provide a predefined local threshold voltage profile along a depth of the particular fin structure.

Preferred developments of the present invention are disclosed herein.

A feature of the present invention is to compensate for or increase a local threshold voltage variation resulting from the variation of the fin width of the fin, in order to achieve a defined local threshold voltage profile along a depth of the particular fin structure. A suitable doping profile of the doping concentration or the charge density of the channel region is used to compensate for or increase said local threshold voltage variation.

In a preferred embodiment of the present invention, a dopant gradient of a doping of the channel region of the fin structure is generated by means of ion implantation. As a result, a doping profile in the channel region can be precisely adjusted.

With one possible example embodiment of the vertical field-effect transistor structure of the present invention, a fin width of the fin structures increases with increasing depth. This may be due to production reasons.

With one possible example embodiment of the vertical field-effect transistor structure of the present invention, the semiconductor layer comprises a silicon carbide layer.

With one possible example embodiment of the vertical field-effect transistor structure of the present invention, the silicon carbide layer is grown epitaxially on the substrate surface of the substrate.

With one possible example embodiment of the vertical field-effect transistor structure of the present invention, the channel region is p-doped.

With one possible alternative example embodiment of the vertical field-effect transistor structure of the present invention, the channel region is n-doped.

With one possible example embodiment of the vertical field-effect transistor structure of the present invention, the predefined local threshold voltage profile has a constant threshold voltage along the depth of the particular fin structure.

With one possible example embodiment of the vertical field-effect transistor structure of the present invention, the predefined local threshold voltage profile has a gradually increasing threshold voltage along the depth of the particular fin structure. This can be advantageous in certain applications when switching the transistor on or off.

With one possible example embodiment of the vertical field-effect transistor structure of the present invention, the predefined local threshold voltage profile has a gradually decreasing threshold voltage along the depth of the particular fin structure. This can be advantageous in certain applications when switching the transistor on or off.

With one possible example embodiment of the vertical field-effect transistor structure of the present invention, the vertical field-effect transistor structure comprises a source electrode on a side of the fin structures directed away from the substrate and a drain electrode on a second substrate surface of the substrate directed away from the first substrate surface.

The plurality of fin structures of the embodiments of the vertical field-effect transistor structure of the present invention described here are thus electrically contacted by the (single) source electrode, which results in a minimal on-resistance or switch-on resistance of the vertical field-effect transistor structure realized in this way.

### BRIEF DESCRIPTION OF THE DRAWINGS

Further features and advantages of the present invention will be explained in the following with reference to the figures.

FIG. 1A-1D are a schematic representation of a conventional vertical field-effect transistor structure with associated profiles of the doping, fin width and local threshold voltage.

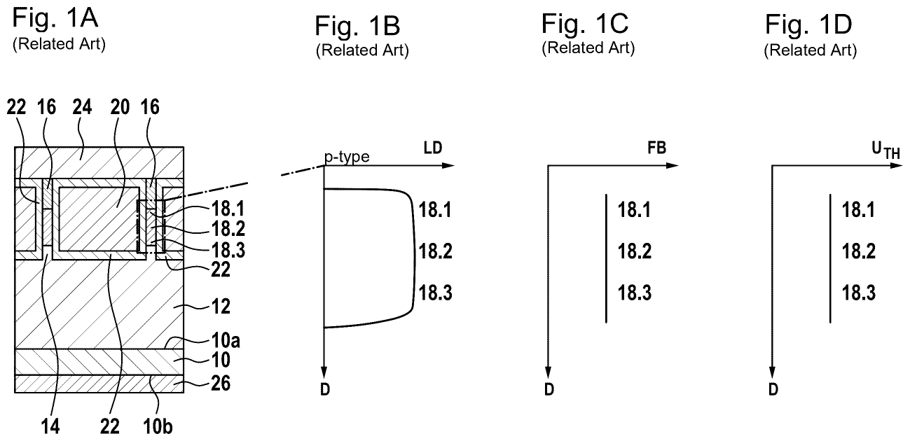

FIG. 2A-2D are a schematic representation of a further conventional vertical field-effect transistor structure with associated profiles of the doping, fin width and local threshold voltage.

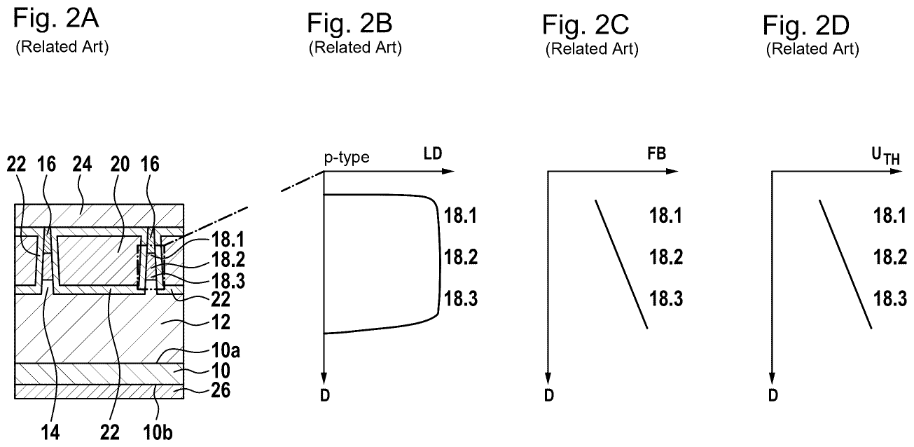

FIG. 3A-3D are a schematic representation of an example embodiment of a vertical field-effect transistor according to the present invention with associated profiles of the doping, fin width and local threshold voltage.

FIG. 4A-4D are a schematic representation of a further example embodiment of a vertical field-effect transistor according to the present invention with associated profiles of the doping, fin width and local threshold voltage.

FIG. 5A-5D are a schematic representation of a further example embodiment of a vertical field-effect transistor according to the present invention with associated profiles of the doping, fin width and local threshold voltage.

FIG. 6A-6D are a schematic representation of a further example embodiment of a vertical field-effect transistor according to the present invention with associated profiles of the doping, fin width and local threshold voltage.

FIG. 7 is a flow chart illustrating an example embodiment of a method according to the present invention for producing a vertical field-effect transistor.

### DETAILED DESCRIPTION OF EXAMPLE EMBODIMENTS

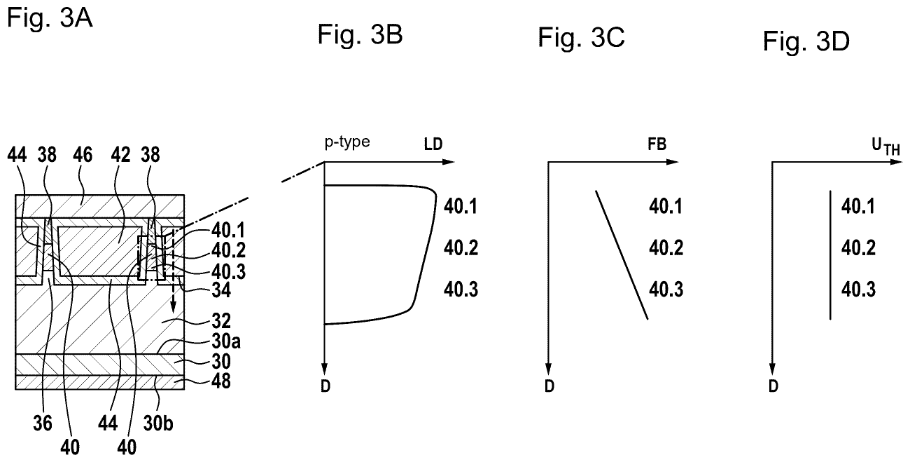

FIG. 3A is a schematic representation of a possible embodiment of the vertical field-effect transistor structure.

The vertical field-effect transistor structure shown schematically in FIG. 3A has a substrate 30 having a first substrate surface 30a and having a second substrate surface 30b directed away from the first substrate surface 30a. Preferably, the substrate 30 is an n-doped substrate 30, specifically a highly n-doped substrate 30. The substrate 30 is preferably an (n-doped/highly n-doped) silicon carbide substrate 30.

A semiconductor layer 32, in particular a silicon carbide layer, is epitaxially grown on the first substrate surface 30a such that the semiconductor layer 32 contacts the first substrate surface 30a of the substrate 30. The first substrate surface 30a can be inclined at an angle of between 2° to 7° relative to the (0001) crystal surface of the silicon carbide substrate 30 along the [112̅0] direction of the silicon carbide substrate 30. This ensures fewer crystal defect structures in the semiconductor layer 32, in particular silicon carbide layer 32, epitaxially grown on the first substrate surface 30a.

The epitaxially grown silicon carbide layer 32 forms a drift zone of the vertical field-effect transistor structure. Therefore, the silicon carbide layer 32 is preferably n-doped, in particular weakly n-doped. A plurality of depressions 34 can be patterned into the silicon carbide layer 32 on a side of the silicon carbide layer 32 directed away from the first substrate surface 30a such that a plurality of fin structures 36 anchored to the silicon carbide layer 32 are patterned out of the silicon carbide layer 32. A minimum width of the depressions 34 aligned parallel to the first substrate surface 30a is greater by at least a factor of 2, preferably by at least a factor of 5, than a maximum width of the fin structures 36 aligned parallel to the first substrate surface 30a. The formation of the fin structures 36 as “narrow” fin structures 36 results in a high channel density and a minimal on-resistance or switch-on resistance of the vertical field-effect transistor structure formed thereby. Preferably, a longitudinal direction aligned parallel to the first substrate surface 30a can be defined for the fin structures 36, in which longitudinal direction the fin structures 36 have their maximum extent. In particular, the longitudinal direction of the fin structures 36 can be perpendicular to the [112̅0] direction of the silicon carbide layer 32. Preferably, an n-doped source region 38 is formed at each end of the fin structures 36 directed away from the substrate 30. The particular n-doped source region 38 of the fin structures 36 can in particular in each case be a heavily n-doped source region 38. With the embodiment shown in FIG. 3A-3D, a p-doped channel region 40 is located on a side of the n-doped source regions 38 of the fin structures 36 that is aligned with the substrate 30.

The vertical field-effect transistor structure of FIG. 3A also has a plurality of gate electrodes 42, although only one of the gate electrodes 42 is shown. Each of the gate electrodes 42 is located between two adjacent fin structures 36. At least one gate dielectric 44 is formed and/or deposited on the vertical field-effect transistor structure such that the fin structures 14 and the silicon carbide layer 32 are electrically insulated from the gate electrodes 42 by means of the at least one gate dielectric 44. In particular, if present, the n-doped source regions 38 and/or the p-doped channel regions 40 can be electrically insulated from the adjacent gate electrode 42 by means of the at least one gate dielectric 44.

With the embodiment shown in FIG. 3A, the FinFET has a source electrode 46 on a side of the fin structures 30 directed away from the substrate 30 and/or a drain electrode 48 on a second substrate surface 30b of the substrate 30 directed away from the first substrate surface 30a.

With the FinFET according to the present invention, a doped channel region 40 is located on a side of the source regions 38 of the fin structures 36 that is aligned with the substrate 30. The doping of the channel region 40 is adjusted to provide a predefined local threshold voltage profile in the vertical direction along the depth D of the particular fin structure 36. FIG. 3A-3D show a first exemplary embodiment of the FinFET according to the present invention with associated profiles. With the exemplary embodiment shown in FIG. 3A-3D, the fin width FB of the fin increases with increasing depth D (depth), as shown in FIG. 3C. The channel region 40 is p-doped with the exemplary embodiment shown in FIG. 3A-3D. The charge density LD of the doping is shown schematically in FIG. 3B. In order to provide a local threshold voltage profile with a threshold voltage Uth that is constant in the vertical direction (see FIG. 3D), the doping of the channel region 40 is designed to be gradually decreasing, as can be seen in FIG. 3B. The channel region 40 is designed with a p-doping that gradually decreases with increasing depth D. The wider the fin becomes in the channel region 40, the lower the p-doping in the channel region 40 of the fin. By appropriately choosing the dopant profile, it is possible for both effects to partially or completely compensate for each other and thus for the profile of the resulting threshold voltage Uth across the fin to be homogeneous or constant in the vertical direction or along the depth D, as can be seen in FIG. 3D. With the exemplary embodiment shown in FIG. 3A to 3D, the charge density of p-type charge carriers is varied in such a way that it compensates for the threshold voltage change caused by the changing fin width FB. With one possible embodiment, a dopant gradient can be easily generated by ion implantation.

In addition to a local threshold voltage Uth that is homogeneous or constant in the vertical direction, i.e. a threshold voltage Uth that is constant in the vertical direction (as shown in FIG. 3D), a controlled variation of the threshold voltage Uth over the height of the fin can also be advantageous, for example for the switch-on or switch-off process of the transistor. However, the controllability of the threshold voltage Uth is limited due to the fin width variation caused by the fin production process. By a suitable choice of the doping gradient in the channel region 40, the threshold voltage Uth in the FinFET according to the present invention can be adjusted locally precisely.

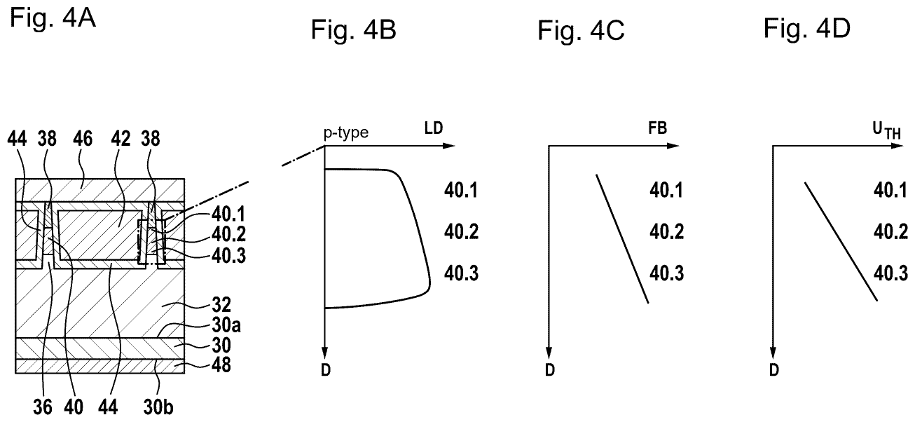

With the exemplary embodiment of the FinFETS shown in FIG. 4A-4D, a higher variation of the threshold voltage Uth is achieved over the fin height or depth D, as shown in FIG. 4D. Here, the p-type charge density LD is chosen to increase gradually in the vertical direction with increasing depth D (as shown in FIG. 4B) in order to further increase or amplify (see FIG. 4D) the effect of the local threshold voltage increase caused by the increase in the fin width FB (see FIG. 4C).

In addition to a gradually increasing or decreasing or constant local threshold voltage Uth, combinations of an increasing/decreasing and constant threshold voltage Uth in a fin are also possible by suitable selection of the dopant profile or the charge density LD of the dopant.

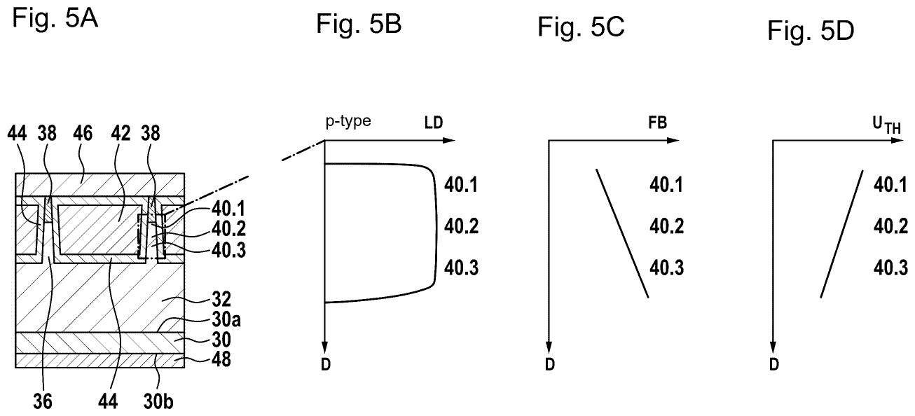

The same mechanism can also be used in FinFETs without p-doping in the channel region. A FinFET, as shown in FIG. 5A, having the uniform n-doping profile having a constant charge density LD shown in FIG. 5B has a spatially deeper and wider fin region (see FIG. 5C) having a lower local threshold voltage Uth, as shown in FIG. 5D.

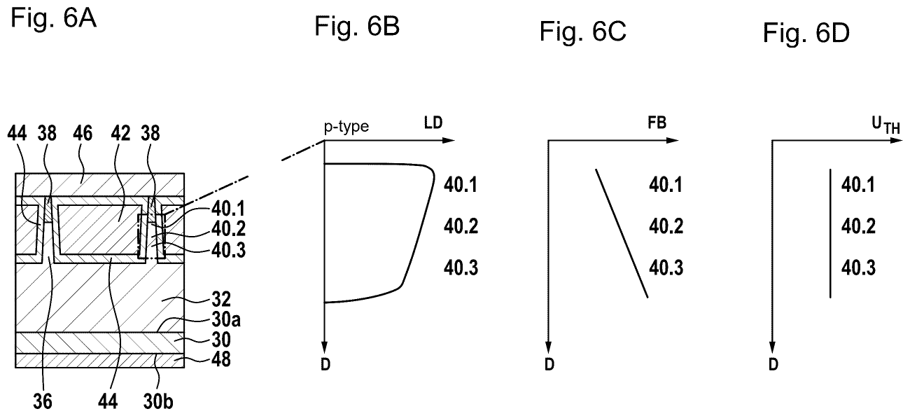

If there is no p-doping in the channel region 40, the n-doping or charge density LD can also be varied as the fin width FB increases (see FIG. 6B) such that in a possible embodiment of the FinFET according to the present invention, as shown in FIG. 6A, a local threshold voltage Uth that is homogeneous or constant in the vertical direction is achieved, as shown in FIG. 6D.

In addition to silicon carbide (Sic), the procedure according to the present invention can also be applied in analog components based on other power semiconductors, in particular GaN, gallium oxide, aluminum nitride or diamond.

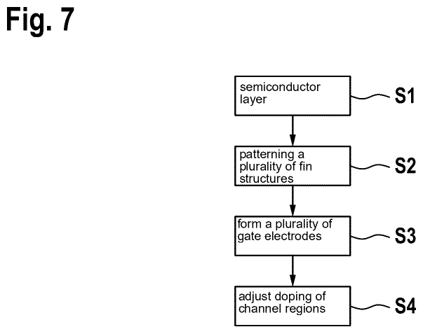

FIG. 7 shows a flow chart for producing a vertical field-effect transistor according to a further aspect of the present invention. The production method according to the present invention comprises a plurality of main steps S, as shown in FIG. 7.

In a first step S1, a semiconductor layer 32 is provided on a first substrate surface 30a of a substrate 30.

With one possible embodiment, the semiconductor layer 32 comprises silicon carbide (SiC) that is epitaxially grown on the first substrate surface 30a of the substrate 30.

In a further step S2, a plurality of fin structures 36 anchored to the semiconductor layer 32 are patterned out of the semiconductor layer 32 on a side of the semiconductor layer 32 directed away from the first substrate surface 30a, wherein a source region 38 is formed at each end of the fin structures 36 directed away from the substrate 30.

For example, strip-shaped starting structures can be patterned out of the semiconductor layer 32 by means of an anisotropic trench process. Alternatively or additionally, the removal method can comprise a thermal oxidation of at least the strip-shaped starting structures and a subsequent etching process for etching the oxidized semiconductor layer 32.

In a further step S3, a plurality of gate electrodes 42 are formed, wherein one of the gate electrodes 42 is arranged between two adjacent fin structures 36. The fin structures 36 and the semiconductor layer 32 are electrically insulated from the gate electrodes 42 by means of at least one formed gate dielectric 44.

After the fin structures 36 are formed, a plurality of gate electrodes 42 can be formed, wherein in each case one of the gate electrodes 42 is arranged between two adjacent fin structures 36. Before the plurality of gate electrodes 42 are formed, at least one gate dielectric 44 is deposited and/or formed such that the fin structures 36 and the silicon carbide layer 32 are electrically insulated from the gate electrodes 42 by means of the at least one gate dielectric 44.

In a further step S4, a doping of channel regions 40, each of which is located on a side of the source regions 38 of the fin structures 36 aligned with the substrate 30, is adjusted to provide a predefined local threshold voltage profile along a depth D of the particular fin structure 36.

With a preferred embodiment, a dopant gradient of a doping of the channel region 40 is generated by means of ion implantation.

Optionally, a source electrode 46 can be formed on a side of the fin structures 30 directed away from the substrate 30 and/or a drain electrode 48 can be formed on a second substrate surface 30b of the substrate 30 directed away from the first substrate surface 30a.

The fin structures 36 can thus be electrically contacted by the single source electrode 46. Preferably, the vertical field-effect transistor structure also comprises a drain electrode 48 fastened to the second substrate surface 30b. With one possible embodiment, the vertical field-effect transistor structure can further comprise p-doped shielding regions, which, however, are not shown in FIG. 3A to 6D for better clarity.

The vertical field-effect transistor structure shown in FIG. 3A to 6D can be used, for example, as a traction inverter, in particular in an electric drive train in an EV/HEV, or as an inverter. The vertical field-effect transistor structure can be used for a variety of devices, such as a household appliance, in particular a washing machine. It should be noted that the usability of the vertical field-effect transistor structure is not limited to any specific application.

1-15. (canceled)

16. A vertical field-effect transistor structure, comprising:
a substrate having a first substrate surface;
a semiconductor layer located on the first substrate surface, a plurality of fin structures anchored to the semiconductor layer being patterned out on a side of the semiconductor layer directed away from the first substrate surface out of the semiconductor layer, wherein a source region is formed at each end of the fin structures directed away from the substrate; and
a plurality of gate electrodes, wherein one of the gate electrodes is located between two adjacent fin structures, and the fin structures and the semiconductor layer are electrically insulated from the gate electrodes by at least one gate dielectric;
wherein a doped channel region is in each case located on a side of the source regions of the fin structures aligned with the substrate, a doping of the doped channel region being adjusted to provide a predefined local threshold voltage profile along a depth of each fin structure.

17. The vertical field-effect transistor structure according to claim 16, wherein a fin width of the fin structures increases with increasing depth.

18. The vertical field-effect transistor structure according to claim 16, wherein the semiconductor layer includes a silicon carbide layer.

19. The vertical field-effect transistor structure according to claim 18, wherein the silicon carbide layer is grown epitaxially on the substrate surface of the substrate.

20. The vertical field-effect transistor structure according to claim 16, wherein the channel region is p-doped.

21. The vertical field-effect transistor structure according to claim 16, wherein the channel region is n-doped.

22. The vertical field-effect transistor structure according to claim 16, wherein the predefined local threshold voltage profile has a constant threshold voltage along the depth of each fin structure.

23. The vertical field-effect transistor structure according to claim 16, wherein the predefined local threshold voltage profile has a gradually increasing threshold voltage along the depth of each fin structure.

24. The vertical field-effect transistor structure according to claim 16, wherein the predefined local threshold voltage profile has a gradually decreasing threshold voltage along the depth of each fin structure.

25. The vertical field-effect transistor structure according to claim 16, wherein the vertical field-effect transistor structure includes a source electrode on a side of the fin structures directed away from the substrate and a drain electrode on a second substrate surface of the substrate directed away from the first substrate surface.

26. A method for producing a vertical field-effect transistor structure, comprising the following steps:
providing a semiconductor layer on a first substrate surface of a substrate;
patterning a plurality of fin structures anchored to the semiconductor layer out of the semiconductor layer on a side of the semiconductor layer directed away from the first substrate surface, wherein a source region is formed at each end of the fin structures directed away from the substrate;
forming a plurality of gate electrodes, wherein one of the gate electrodes is arranged between two adjacent fin structures and the fin structures and the semiconductor layer are electrically insulated from the gate electrodes by at least one gate dielectric; and
adjusting a doping of channel regions, each of which being located on a side of the source regions of the fin structures aligned with the substrate, to provide a predefined local threshold voltage profile along a depth of each fin structure.

27. The method according to claim 26, wherein a dopant gradient of a doping of each channel region is generated by ion implantation.

28. The method according to claim 26, wherein the semiconductor layer includes silicon carbide epitaxially grown on the first substrate surface of the substrate.

29. The method according to claim 26, wherein each channel region is p-doped.

30. The method according to claim 26, wherein each channel region is n-doped.
